(19) United States
(12) Patent Application Publication
(10) Pub. No.: US 2024/0097077 A1
(43) Pub. Date: Mar. 21, 2024

(54) BARRIER STRUCTURE FOR DISPLAY DEVICE AND MANUFACTURING METHOD THEREOF

(71) Applicant: KOREA ELECTRONICS TECHNOLOGY INSTITUTE, Seongnam-si (KR)

(72) Inventors: Chul Jong HAN, Yongin-si (KR); Yeong Beom LEE, Ansan-si (KR); Jeongno LEE, Yongin-si (KR); Kyoungwon PARK, Seoul (KR); Young Ji LIM, Daejeon (KR)

(21) Appl. No.: 18/470,217

(22) Filed: Sep. 19, 2023

(30) Foreign Application Priority Data
Sep. 21, 2022 (KR) 10-2022-0119275

(51) Int. Cl. H01L 33/46; H01L 25/075

(52) U.S. Cl. CPC H01L 33/46; H01L 25/0753; H01L 2933/0025

(57) ABSTRACT

A barrier structure of a display device and a method of manufacturing the same are proposed. The barrier structure may include a plurality of light-transmissive photoresist patterns disposed on a substrate at predetermined intervals. The barrier structure may also include reflective films formed on an entire outer surface of the light-transmissive photoresist patterns.

### CROSS-REFERENCE TO RELATED APPLICATION

This application claims priority to and the benefit of Korean Patent Application No. 10-2022-0119275, filed on Sep. 21, 2022, the disclosure of which is incorporated herein by reference in its entirety.

### BACKGROUND

### Technical Field

The present disclosure relates to a barrier structure for a display device and manufacturing method thereof, and more particularly, to a barrier structure of a display device and a method of manufacturing the same, which can be applied to displays and sensor devices using phosphors, and can be applied to light emitting devices such as mini or micro LEDs.

### Description of the Related Technology

In general, many displays or photoelectric devices use barrier structures around pixels to block light.

### SUMMARY

One aspect is a barrier structure for a display device and a manufacturing method thereof, which may minimize a light absorption phenomenon of the barrier structure having a high aspect ratio in the display device.

Another aspect is a barrier structure for a display device and a manufacturing method thereof, which may increase a thickness of a barrier structure for separating pixels in the display device and thus form a light conversion structure within the pixel more thickly.

Another aspect is a barrier structure of a display device that may include a plurality of light-transmissive photoresist patterns disposed on a substrate at predetermined intervals; and reflective films formed on an entire outer surface of the light-transmissive photoresist patterns.

In an embodiment of the present disclosure, a thickness of the light-transmissive photoresist patterns may be 2 μm to 200 μm.

In an embodiment of the present disclosure, a thickness of the light-transmissive photoresist patterns may be 10% to 80% of the intervals between the light-transmissive photoresist patterns.

In an embodiment of the present disclosure, the reflective films may have a reflectance of 50% or more with respect to a light wavelength of 430 nm to 650 nm.

In an embodiment of the present disclosure, a thickness of the reflective films may be 50 nm to 500 nm.

In an embodiment of the present disclosure, the barrier structure may further comprise non-transmissive photoresist patterns disposed under the light-transmissive photoresist patterns or on the reflective films of an upper side of the light-transmissive photoresist patterns.

In an embodiment of the present disclosure, a thickness of the non-transmissive photoresist patterns may be 0.5 μm to 3 μm.

Another aspect is a method of manufacturing the barrier structure of the display device that may include a) applying a light-transmissive photoresist on a substrate; b) forming light-transmissive photoresist patterns spaced apart from each other at predetermined intervals by exposing and developing the light-transmissive photoresist; and c) forming reflective films on an entire upper surface and an entire side surface of the light-transmissive photoresist patterns.

In an embodiment of the present disclosure, the light-transmissive photoresist may be applied to a thickness of 2 μm to 200 μm.

In an embodiment of the present disclosure, a thickness of the light-transmissive photoresist patterns may be manufactured to be 10% to 80% of the intervals between the light-transmissive photoresist patterns.

In an embodiment of the present disclosure, the reflective films may be formed by depositing and patterning a metal or oxide having a reflectance of 50% or more with respect to a light wavelength of 430 nm to 650 nm.

In an embodiment of the present disclosure, the reflective films may be formed to a thickness of 50 nm to 500 nm.

In an embodiment of the present disclosure, the method may further comprising non-transmissive photoresist patterns disposed under the light-transmissive photoresist patterns or on the reflective films of an upper side of the light-transmissive photoresist patterns.

In an embodiment of the present disclosure, the non-transmissive photoresist patterns may be formed to a thickness of 0.5 μm to 3 μm.

The present disclosure has an effect of forming a pattern with a thickness greater than that of a conventional BM material, forming a photoresist pattern with a high light transmittance and forming a reflective film on a surface of the photoresist pattern, thereby minimizing light absorption phenomenon in the barrier structure.

In addition, the present disclosure has an effect of forming a barrier structure using a material thicker greater than a conventional BM material, thereby forming a thickness of a light conversion structure using a fluorescent material or a light absorbing material to be more thick, and improving color purity according to an increase in the thickness of the light conversion structure.

### BRIEF DESCRIPTION OF THE DRAWINGS

FIG. 1 is cross-sectional views of a manufacturing process of a barrier structure.

FIGS. 2A to 2D are cross-sectional views illustrating a process of manufacturing a barrier structure according to an embodiment of the present disclosure.

FIG. 3 is a cross-sectional configuration diagram of a barrier structure according to another embodiment of the present disclosure.

FIGS. 4A to 4D are cross-sectional views of a subsequent process of after forming the barrier structure according to an embodiment of the present disclosure.

FIG. 5 is a cross-sectional configuration of a subsequent process using FIG. 3.

### DETAILED DESCRIPTION

A flat color display includes RGB pixels, and the target resolution of the display is implemented by designing the pixels smaller or by enlarging the panel. However, there is a need for a very small high-brightness and high-resolution display of about 15 mm×10 mm or less for virtual reality and augmented reality. Therefore, in order to provide the display with a target resolution in a small panel, it may be achieved only by designing a smaller pixel.

Compared to a technology for individually emitting light emitting devices such as AMOLEDs with R, G, and B, a technology for emitting only the Blue, which is a short wavelength, and emitting the Red and the Green using a phosphor such as a quantum dot can be more convenient and economically competitive. To this end, a material including a phosphor needs to be laminated and applied on a short wavelength light emitting pixel, but its thickness is a problem.

For example, in the case of a pixel that represents a green color by changing a blue light source into a green color, all the blue colors should be absorbed and all absorbed blue colors must be changed into a green color, but when the optical density of the phosphor material is not high enough, the blue color that has not been absorbed is transmitted, and thus the color purity is deteriorated because the color is not the target green but a mixture of blue and green. In order to solve this problem, it is necessary to increase a concentration of the phosphor, increase an absorption coefficient, increase its thickness, or form a separate layer for cutting off the blue wavelength such as a color filter.

In the related art, even if the concentration is optimized and the absorption coefficient is maximized, the thickness of the current phosphor must be formed at a level of 10 μm or more to maintain the color purity usable for the display. Therefore, the barrier structure having a thickness of 10 μm or more is formed, and R and G phosphor materials are pattern-applied in the structure to solve the problem.

At this time, there are several requirements to form the barrier structure having a height of 10 μm. Specifically, a photoresist having a thickness of 10 μm or more and a resolution of 2 μm or less in a barrier width should be required, and a transmittance should be sufficiently low to prevent color mixing between each sub-pixel. In order to meet these characteristics, a barrier is formed using a black photoresist called a black matrix (BM).

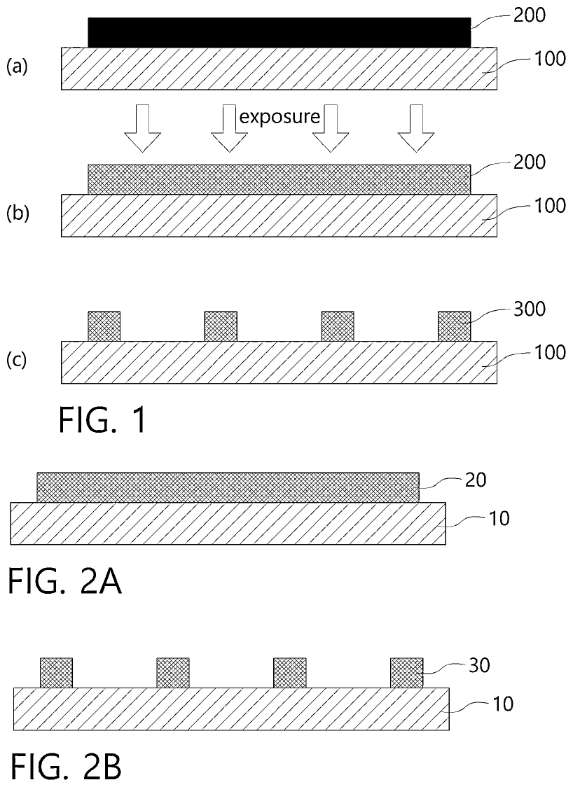

FIG. 1 is a cross-sectional view of a manufacturing process of a barrier structure of a display device using BM. Referring to FIG. 1, a barrier structure using BM includes applying a BM 200 on a substrate 100 ((a) of FIG. 1), curing a portion of the applied BM 200 through exposure using a mask ((b) of FIG. 1), and patterning the exposed BM 200 through a developing process to form a barrier structure 300 ((c) of FIG. 1).

The process of applying the BM 200 on the substrate 100 may include applying (or coating) a liquid BM solution to a thickness of 1 μm or less. Then, a portion of the applied BM 200 is cured using a photo mask, and an uncured portion is removed using a developing solution to form the barrier structure 300 made of a single BM material.

However, since the BM absorbs light due to its characteristics, the thicker, the light is blocked, and thus it is difficult to form a fine pattern more than a certain thickness. In addition, since the light is absorbed in black, the light emitted by the phosphor is absorbed by the barrier, and thus the light emission efficiency is reduced.

To fully understand the construction and effects of the present disclosure, embodiments of the present disclosure will be described with reference to the accompanying drawings. However, the present disclosure is not limited to the embodiments disclosed below, and may be implemented in various ways and may be modified. The description of the present embodiments is provided merely to make the disclosure of the present disclosure complete, and to fully inform a person skilled in the art of the present disclosure. In the accompanying drawings, components are shown to enlarge their size than the actual size for convenience of description, and the ratio of each component may be exaggerated or reduced.

Terms such as ‘first’, ‘second’, etc., may be used to describe various components, but the components should not be limited by the above terms. The above terms may be used only to distinguish one component from another. For example, ‘first component’ may be referred to as ‘second component’, and similarly, ‘second component’ may be referred to as ‘first component’ without departing from the scope of the present disclosure. In addition, the singular expression includes a plural expression unless the context clearly dictates otherwise. The terms used in the embodiments of the present disclosure may be interpreted as a meaning commonly known to a person skilled in the art unless otherwise defined.

Hereinafter, a barrier structure of a display device and a method of manufacturing the same according to an embodiment of the present disclosure will be described in detail with reference to the accompanying drawings.

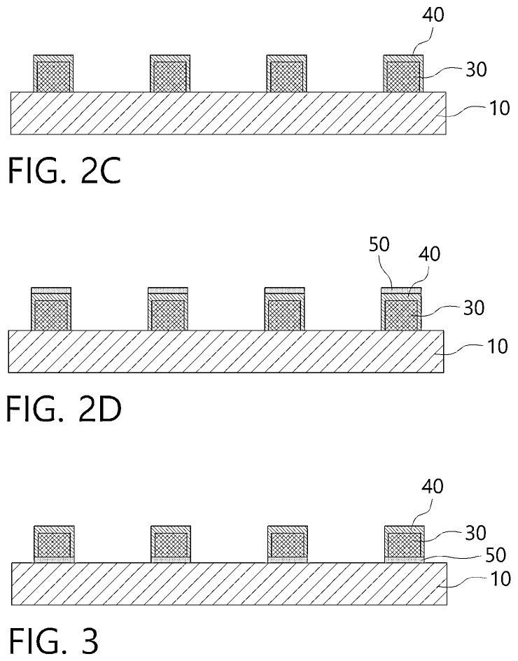

FIGS. 2A to 2D are cross-sectional views illustrating a process of manufacturing a barrier structure of a display device according to an embodiment of the present disclosure.

Referring to FIGS. 2A to 2D, the present disclosure includes applying a light-transmissive photoresist 20 on a substrate 10 (FIG. 2A), forming each light-transmissive photoresist pattern 30 by exposing and developing the light-transmissive photoresist 20 (FIG. 2B), forming reflective films 40 on an entire surface of each of the light-transmissive photoresist patterns 30 (FIG. 2C), and forming non-transmissive photoresist patterns 50 on each of the reflective films 40 (FIG. 2D).

Hereinafter, a configuration and operation of the method of manufacturing the barrier structure of the display device according to an embodiment of the present disclosure configured as described above will be described in more detail.

First, as illustrated in FIG. 2A, the light-transmissive photoresist 20 is applied on the substrate 10. In this case, it is assumed that the light-transmissive photoresist 20 has high light transmittance in a solution state. Specifically, one having a light transmittance of 30% or more at a thickness of 1 cm is used.

The thickness of the light-transmitting photoresist 20 is applied to a thickness of 2 μm to 200 μm. For example, it can be made to have a thickness of 4 μm to 15 μm.

Then, as shown in FIG. 2B, the applied light-transmissive photoresist 20 is selectively exposed using a photo mask, and developed using a developer to form the light-transmissive photoresist patterns 30.

In this case, a space between the light-transmissive photoresist patterns 30 becomes a sub-pixel region.

The distance between the light-transmissive photoresist patterns 30 and the height of the light-transmissive photoresist pattern 30 may be at least 10:1 or more.

That is, the height of the light-transmissive photoresist pattern 30 is assumed to be 10% or more with respect to the distance between the light-transmissive photoresist patterns 30, for example, 10% to 80%.

Next, as shown in FIG. 2C, the reflective films 40 covering the entire upper surface and the entire side surface of the light-transmissive photoresist patterns 30 are formed.

In this case, the reflective film 40 may be a metal film or an oxide film.

That is, the reflective films 40 selectively covering the light-transmissive photoresist patterns 30 may be formed by depositing the metal film or the oxide film and patterning it through a photolithography process.

The thickness of the reflective film 40 is formed to have a thickness of 50 nm to 500 nm.

The reflective film 40 is selected to have a reflectance of 50% or more in an optical wavelength region of 430 nm to 650 nm and a light transmittance of at least 20% or less.

In particular, the reflective film 40 may be a metal, and may be a single-layer or multi-layer composite structure of a metal material having a reflectance of 50% or more, such as Al, Ag, Pt, Ni, or Mo.

In this way, when the reflective film 40 is used as the metal material, the reflective film 40 may be used as a heat sink for dissipating heat generated in the display device. That is, the use of the reflective film 40 may dissipate heat generated in the display device, thereby preventing a deterioration phenomenon of the display device due to heat.

As described above, the present disclosure may form the barrier structure having a thick thickness using a light-transmissive photoresist, and may form the reflective films on the entire light-transmissive photoresist patterns to prevent occurrence of an absorption phenomenon.

In addition, in order to prevent light from leaking in the barrier structure portion, the non-transmissive photoresist patterns 50, which is a black matrix BM, may be formed on the upper portion of each of the reflective films 40 as shown in FIG. 2D.

The non-transmissive photoresist pattern 50 may be formed to have a thickness of 0.5 μm to 3 μm, for example, 1 μm to 2 μm.

The non-transmissive photoresist patterns 50 may be formed by applying, exposing, and developing BM.

Although FIG. 2D illustrates an example in which the non-transmissive photoresist patterns 50 are formed on the reflective films 40 on the upper side of each of the light-transmissive photoresist pattern 30, the non-transmissive photoresist patterns 50 may be formed to be positioned under each light-transmissive photoresist pattern 30.

FIG. 3 is a cross-sectional configuration diagram of a barrier structure according to another embodiment of the present disclosure.

Referring to FIG. 3, the non-transmissive photoresist patterns 50 may be formed to be positioned on the lower side of each light-transmissive photoresist pattern 30.

That is, the BM is applied on the substrate 10, exposed and developed to form a non-transmissive photoresist patterns 50, and then the light-transmissive photoresist patterns 30 is formed on each of non-transmissive photoresist patterns 50 to be manufactured.

The formation of the light-transmissive photoresist patterns 30 and the reflective films 40 may be performed by the method described in detail above.

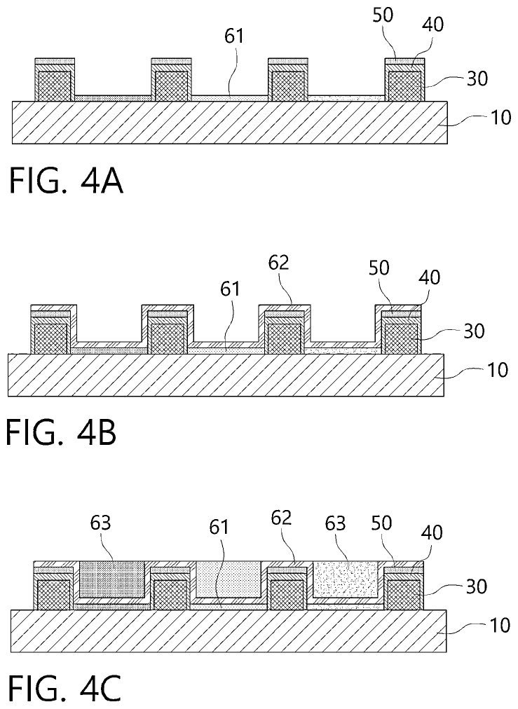

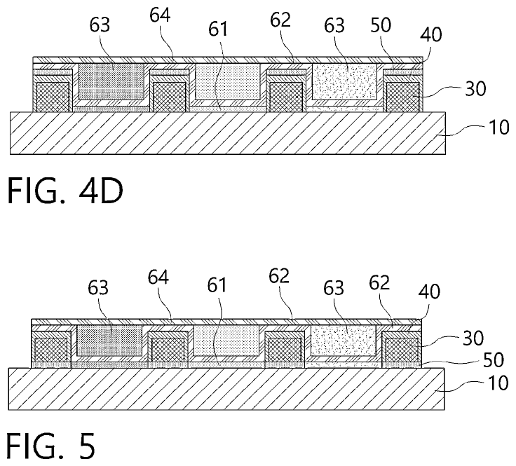

FIGS. 4A to 4D are cross-sectional views of a subsequent process after the barrier structure manufacturing process described with reference to FIGS. 2A to 2D.

Referring to FIGS. 4A to 4D, color filters 61 are formed in the sub-pixel region between the barrier structures, a distributed bragg reflector (DBR) layer 62 covering the entire upper surface of the structure in which the color filters 61 are formed, and quantum dots (QD) 63 are formed on the DBR layer 62 of the upper side of each color filter 61.

Finally, an encapsulation layer 64 is formed on the entire upper portion of each quantum dot 63 and the entire upper portion of the exposed DBR layer 62.

In the above example, the color filters 61, the DBR layer 62, the quantum dots 63, and the encapsulation layer 64 form a light conversion layer, and as mentioned above, the present disclosure can manufacture the barrier structures having a thick thickness using the light-transmissive photoresist patterns 30, and also a thickness of the light conversion layers disposed between the barrier structures can be formed to be thicker than conventional one.

Specifically, the color filter 61 of RGB colors may be formed to have a thickness of 1 μm to 5 μm.

The blue (B) may be formed of a blue color filter, a blue quantum dot, or a brightness control layer of a blue color. The DBR layer 62 serves to block excessive blue light and may be formed under the color filters 61, unlike the above example.

The present disclosure relates to a barrier structure, and is not limited to a structure of a light conversion layer.

The quantum dot 63 is formed to have a thickness of 4 μm to 15 μm, and extract light energy of various wavelengths and convert it into light of a unique wavelength.

The encapsulation layer 64 performs a function of planarizing to prevent empty spaces or irregularities from occurring, and is formed for protection from harmful factors such as heat, oxygen, and water.

Additionally, the encapsulation layer 64 may have an adhesive function so that devices such as LEDs may be mounted thereon later.

FIG. 5 is an exemplary diagram of a subsequent process for the configuration of FIG. 3, and is substantially the same as the example of the light conversion layer described with reference to FIGS. 4A to 4D, so detailed description is omitted.

As described above, the present disclosure may provide a barrier structure having a thick thickness using the light-transmissive photoresist patterns 30 and a reflective layer 40, thereby minimizing the occurrence of light absorption in the barrier structure.

In addition, the thickness of the barrier structure can be formed to be thicker than the conventional one, and the thickness of the light conversion layer disposed between the barrier structures can be formed to be thicker than the conventional one, thereby preventing the degradation of color purity.

Although the embodiments of the present disclosure have been described above, these are merely exemplary, and it will be understood by those skilled in the art that various modifications and equivalent embodiments are possible. Accordingly, the true technical protection scope of the present disclosure should be determined by the following claims.

What is claimed is:

1. A barrier structure comprising:
a plurality of light-transmissive photoresist patterns disposed on a substrate at predetermined intervals; and
reflective films formed on an entire outer surface of the light-transmissive photoresist patterns.

2. The barrier structure of claim 1, wherein a thickness of the light-transmissive photoresist patterns is 2 μm to 200 μm.

3. The barrier structure of claim 1, wherein a thickness of the light-transmissive photoresist patterns is 10% to 80% of the intervals between the light-transmissive photoresist patterns.

4. The barrier structure of claim 1, wherein the reflective films have a reflectance of 50% or more with respect to a light wavelength of 430 nm to 650 nm.

5. The barrier structure of claim 1, wherein a thickness of the reflective films is 50 nm to 500 nm.

6. The barrier structure of claim 1, further comprising:
non-transmissive photoresist patterns disposed under the light-transmissive photoresist patterns or on the reflective films of an upper side of the light-transmissive photoresist patterns.

7. The barrier structure of claim 6, wherein a thickness of the non-transmissive photoresist patterns is 0.5 μm to 3 μm.

8. A method of manufacturing a barrier structure, the method comprising:
applying a light-transmissive photoresist on a substrate;
forming light-transmissive photoresist patterns spaced apart from each other at predetermined intervals by exposing and developing the light-transmissive photoresist; and
forming reflective films on an entire upper surface and an entire side surface of the light-transmissive photoresist patterns.

9. The method of claim 8, wherein the light-transmissive photoresist is applied to a thickness of 2 μm to 200 μm.

10. The method of claim 8, wherein a thickness of the light-transmissive photoresist patterns is manufactured to be 10% to 80% of the intervals between the light-transmissive photoresist patterns.

11. The method of claim 8, wherein the reflective films are formed by depositing and patterning a metal or oxide having a reflectance of 50% or more with respect to a light wavelength of 430 nm to 650 nm.

12. The method of claim 11, wherein the reflective films are formed to have a thickness of 50 nm to 500 nm.

13. The method of claim 8, further comprising:
forming non-transmissive photoresist patterns disposed under the light-transmissive photoresist patterns or on the reflective films of an upper side of the light-transmissive photoresist patterns.

14. The method of claim 13, wherein the non-transmissive photoresist patterns are formed to have a thickness of 0.5 μm to 3 μm.
